(19) United States
(12) Patent Application Publication
(10) Pub. No.: US 2025/0248311 A1
(43) Pub. Date: Jul. 31, 2025

(54) METHOD OF FABRICATING MAGNETIC MEMORY DEVICE

(71) Applicant: Samsung Electronics Co., Ltd., Suwon-si (KR)

(72) Inventors: Jinho PARK, Suwon-si (KR); Hyung-Yong KIM, Suwon-si (KR)

(21) Appl. No.: 18/812,022

(22) Filed: Aug. 22, 2024

(30) Foreign Application Priority Data
Jan. 29, 2024 (KR) 10-2024-0013395

(51) Int. Cl. H10N 50/01; H10B 61/00; H10N 50/10

(52) U.S. Cl. CPC H10N 50/01; H10B 61/00; H10N 50/10

(57) ABSTRACT

A method of fabricating a magnetic memory device may include sequentially forming a first magnetic layer, a tunnel barrier, and a second magnetic layer on a substrate, performing a first etching process of sequentially etching the second magnetic layer, the tunnel barrier, and the first magnetic layer to form a magnetic tunnel junction pattern and an etch residue layer on a side surface of the magnetic tunnel junction pattern, performing a second etching process to remove at least a portion of the etch residue layer, and performing a third etching process to remove an additional portion of the etch residue layer, after the second etching process. The third etching process may include supplying a neutral gas onto the etch residue layer and irradiating a first ion beam at a first inclination angle relative to a top surface of the substrate.

### CROSS-REFERENCE TO RELATED APPLICATIONS

This U.S. non-provisional patent application claims priority under 35 U.S.C. § 119 to Korean Patent Application No. 10-2024-0013395, filed on Jan. 29, 2024, in the Korean Intellectual Property Office, the entire contents of which are hereby incorporated by reference.

### BACKGROUND

The present disclosure relates to a method of fabricating a magnetic memory device.

As the demand for electronic devices with increased speed and/or reduced power consumption increases, the demand for semiconductor memory devices with faster operating speeds and/or lower operating voltages is increasing. A magnetic memory device has been proposed as a semiconductor memory device that may satisfy this demand. Due to their high speed operation and/or nonvolatility, magnetic memory devices are emerging as a next-generation semiconductor memory device. In general, a magnetic memory device includes a magnetic tunnel junction (MTJ) pattern. The MTJ pattern includes two magnetic layers and an insulating layer interposed therebetween. An electric resistance of the MTJ pattern may vary depending on magnetization directions of the magnetic layers. For example, the electrical resistance of the MTJ pattern is higher when magnetization directions of the magnetic layers are anti-parallel to each other than when they are parallel to each other. Such a difference in electrical resistance can be used for data writing/reading operations of the magnetic memory device. As the electronics industry advances, there is an increasing demand for magnetic memory devices with a high integration density and/or a low power consumption property, and furthermore, many studies are being conducted to improve the reliability of magnetic memory devices.

### SUMMARY

An embodiment of the inventive concept provides a method of fabricating a magnetic memory device with improved reliability.

According to an embodiment of the inventive concept, a method of fabricating a magnetic memory device may include sequentially forming a first magnetic layer, a tunnel barrier, and a second magnetic layer on a substrate, performing a first etching process of sequentially etching the second magnetic layer, the tunnel barrier, and the first magnetic layer to form a magnetic tunnel junction pattern and an etch residue layer on a side surface of the magnetic tunnel junction pattern, performing a second etching process to remove at least a portion of the etch residue layer, and performing a third etching process to remove an additional portion of the etch residue layer, after the second etching process. The third etching process may include supplying a neutral gas onto the etch residue layer and irradiating a first ion beam at a first inclination angle relative to a top surface of the substrate.

According to an embodiment of the inventive concept, a method of fabricating a magnetic memory device may include sequentially forming a first magnetic layer, a tunnel barrier, and a second magnetic layer on a substrate, performing a first etching process of sequentially etching the second magnetic layer, the tunnel barrier, and the first magnetic layer to form a magnetic tunnel junction pattern and an etch residue layer on a side surface of the magnetic tunnel junction pattern, performing a second etching process to remove at least a portion of the etch residue layer, and performing a third etching process to remove an additional portion of the etch residue layer, after the second etching process. The first etching process, the second etching process, and the third etching process may include a first ion beam etching process, a second ion beam etching process, and a third ion beam etching process, respectively. The third etching process may further include supplying a neutral gas onto the etch residue layer, and the supplying of the neutral gas and the third ion beam etching process may be performed simultaneously.

According to an embodiment of the inventive concept, a method of fabricating a magnetic memory device may include sequentially forming a first magnetic layer, a tunnel barrier, and a second magnetic layer on a substrate, performing a first etching process of sequentially etching the second magnetic layer, the tunnel barrier, and the first magnetic layer to form a magnetic tunnel junction pattern and an etch residue layer on a side surface of the magnetic tunnel junction pattern, performing a second etching process to remove at least a portion of the etch residue layer, and performing a third etching process to remove an additional portion of the etch residue layer, after the second etching process. The first etching process, the second etching process, and the third etching process may include a first ion beam etching process, a second ion beam etching process, and a third ion beam etching process, respectively. The third etching process may further include supplying a neutral gas onto the etch residue layer, and the first, second, and third etching processes may be performed in the same process chamber. A vacuum pump connected to the process chamber may be operated during the supplying of the neutral gas and the third ion beam etching process.

### BRIEF DESCRIPTION OF THE DRAWINGS

FIG. 1 is a circuit diagram illustrating a unit memory cell of a magnetic memory device according to an embodiment of the inventive concept.

FIG. 2A is a plan view illustrating a magnetic memory device according to an embodiment of the inventive concept.

FIG. 2B is a sectional view taken along a line I-I′ of FIG. 2.

FIG. 3 is a schematic diagram illustrating a substrate processing apparatus, which is operated using an ion beam and is used for a process of fabricating a magnetic memory device, according to an embodiment of the inventive concept.

FIG. 4A is a flow chart illustrating a process of fabricating a magnetic memory device according to an embodiment of the inventive concept.

FIG. 4B is a flow chart illustrating the operation S4 of FIG. 4A.

FIGS. 5A to 5F are sectional views, which are taken along the line I-I′ of FIG. 2, to illustrate a method of fabricating a magnetic memory device according to an embodiment of the inventive concept.

FIGS. 6A to 6C are conceptual diagrams illustrating a process of removing an etch residue, which is shown in FIGS. 5D and 5E, according to an embodiment of the inventive concept.

FIGS. 7A to 7C are conceptual diagrams illustrating a process of removing an etch residue, which is shown in FIGS. 5D and 5E, according to an embodiment of the inventive concept.

### DETAILED DESCRIPTION

Example embodiments of the inventive concepts will now be described more fully with reference to the accompanying drawings, in which example embodiments are shown. Like reference numerals in the drawings denote like elements, and thus their description will be omitted. In the following drawings, thicknesses or sizes of each layer are exaggerated for convenience of explanation, and thus the thicknesses or sizes of each layer may slightly differ from the actual shapes and proportions. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

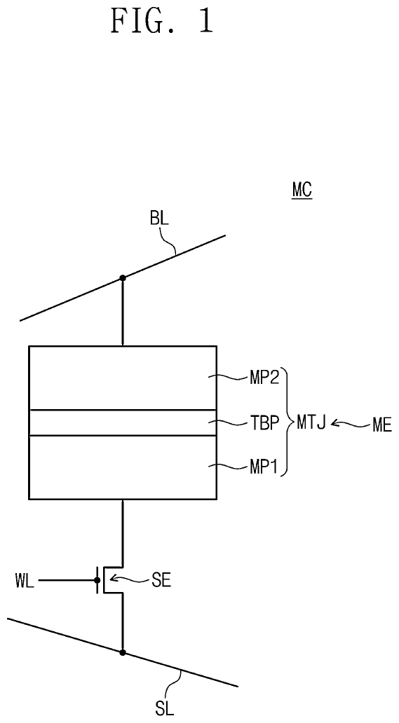

FIG. 1 is a circuit diagram illustrating a unit memory cell of a magnetic memory device according to an embodiment of the inventive concept.

Referring to FIG. 1, a unit memory cell MC may include a memory element ME and a selection element SE. The memory element ME and the selection element SE may be electrically connected to each other in series. The memory element ME may be provided between, and connected to, a bit line BL and the selection element SE. The selection element SE may be provided between, and connected to, the memory element ME and a source line SL and may be controlled by a word line WL. The selection element SE may include, for example, a bipolar transistor or a metal-oxide-semiconductor (MOS) field effect transistor.

The memory element ME may include a magnetic tunnel junction pattern MTJ, and the magnetic tunnel junction pattern MTJ may include a first magnetic pattern MP1, a second magnetic pattern MP2, and a tunnel barrier pattern TBP between the first and second magnetic patterns MP1 and MP2. One of the first and second magnetic patterns MP1 and MP2 may be a reference magnetic pattern, which has a fixed magnetization direction, regardless of the presence or absence of an external magnetic field generated under a typical usage environment. The other of the first and second magnetic patterns MP1 and MP2 may be a free magnetic pattern, whose magnetization direction can be changed to one of two stable magnetization directions by an external magnetic field. The electrical resistance of the magnetic tunnel junction pattern MTJ may be much greater when the magnetization directions of the reference and free magnetic patterns are antiparallel to each other than when they are parallel to each other. This means that the electrical resistance of the magnetic tunnel junction pattern MTJ can be controlled by changing the magnetization direction of the free magnetic pattern. Thus, a difference in electrical resistance of the magnetic tunnel junction pattern MTJ, which is caused by a difference in magnetization direction between the reference and free magnetic patterns, may be used to change data that is stored in the memory element ME of the unit memory cell MC.

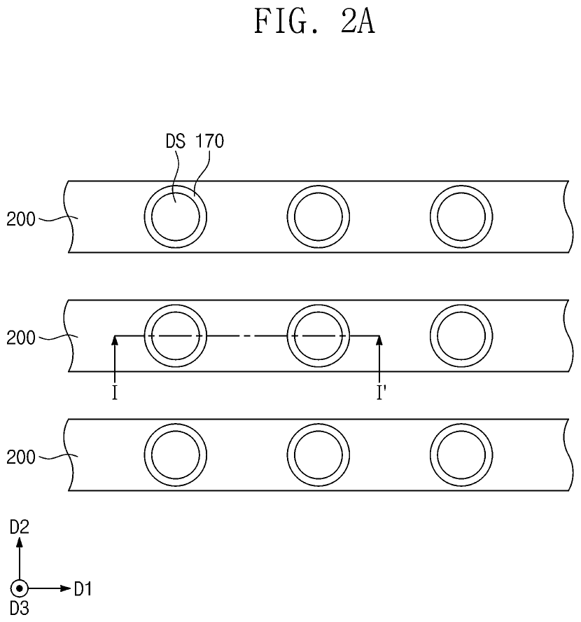

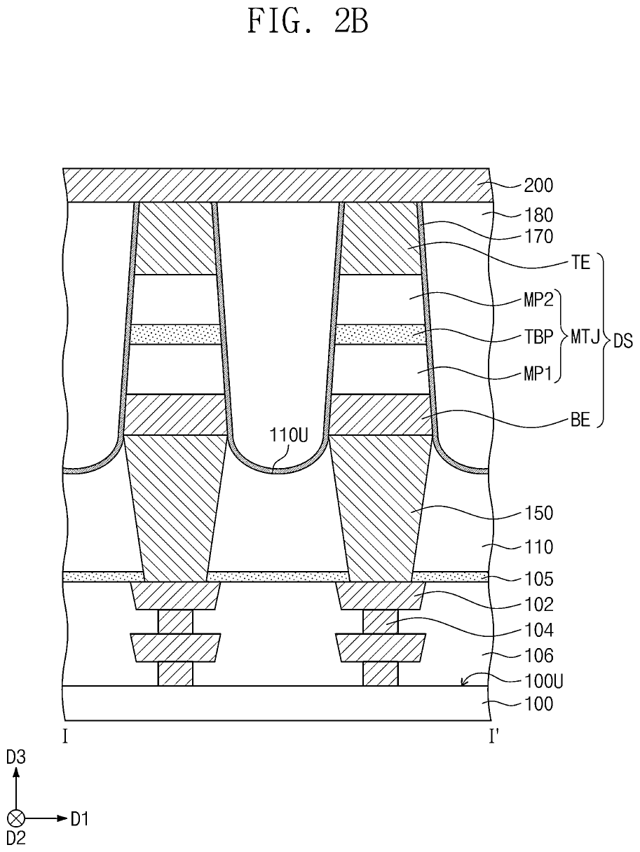

FIG. 2A is a plan view illustrating a magnetic memory device according to an embodiment of the inventive concept. FIG. 2B is a sectional view taken along a line I-I′ of FIG. 2A.

Referring to FIGS. 2A and 2B, a substrate 100 may be provided. In the present specification, a first direction D1 may be parallel to a top surface 100U of the substrate 100. A second direction D2 may be parallel to the top surface 100U of the substrate 100 and may be perpendicular to the first direction D1. A third direction D3 may be perpendicular to the top surface 100U of the substrate 100.

The substrate 100 may be a semiconductor substrate, which is formed of or includes at silicon (Si), silicon germanium (SiGe), germanium (Ge), and/or gallium arsenide (GaAs), or may be a silicon-on-insulator (SOI) wafer. Selection elements (not shown) may be provided on the substrate 100. The selection elements may be field effect transistors or diodes. The selection elements may be connected to the word line WL of FIG. 1. Each of the lower interconnection lines 102 may be electrically connected to a terminal (e.g., a drain terminal) of a corresponding one of the selection elements through a corresponding one of lower contacts 104.

A lower insulating layer may be provided on the substrate 100. The lower insulating layer may include a first lower interlayer insulating layer 106, an etch stop layer 105, and a second lower interlayer insulating layer 110. The second lower interlayer insulating layer 110 may be disposed on the first lower interlayer insulating layer 106. The etch stop layer 105 may be disposed between the first and second lower interlayer insulating layers 106 and 110. Each of the first and second lower interlayer insulating layers 106 and 110 may be formed of or include an oxide, nitride, and/or oxynitride materials. Each of the first and second lower interlayer insulating layers 106 and 110 may be formed of or include tetraethyl orthosilicate (TEOS). The etch stop layer 105 may include a material different from the first and second lower interlayer insulating layers 106 and 110. The etch stop layer 105 may include a material having an etch selectivity with respect to the first and second lower interlayer insulating layers 106 and 110. The etch stop layer 105 may be formed of or include one or more nitride materials (e.g., silicon nitride).

A lower interconnection structure 102/104 may be disposed on the substrate 100. The lower interconnection structure 102/104 may be disposed in the first lower interlayer insulating layer 106. The lower interconnection structure 102/104 may include the lower interconnection lines 102, which are vertically (e.g., third direction D3) spaced apart from the substrate 100, and the lower contacts 104, which are connected to the lower interconnection lines 102. The lower interconnection lines 102 may be spaced apart from the top surface 100U of the substrate 100 in the third direction D3. The lower contacts 104 may be disposed between the substrate 100 and the lower interconnection lines 102, and each of the lower interconnection lines 102 may be electrically connected to the substrate 100 through a corresponding one of the lower contacts 104. The lower interconnection lines 102 and the lower contacts 104 may be formed of or include one or more metallic materials (e.g., copper).

A lower contact plug 150 may be provided to penetrate or extend through the second lower interlayer insulating layer 110 and the etch stop layer 105 and may be electrically connected to the substrate 100. The lower contact plug 150 may be electrically connected to the uppermost one of the lower interconnection lines 102 and may be electrically connected to a terminal (e.g., a source/drain terminal) of the selection element. A top surface of the lower contact plug 150 may be located at a level that is higher (e.g., in the third direction D3) than a recessed top surface 110U of the second lower interlayer insulating layer 110. The lower contact plug 150 may be formed of or include doped semiconductor materials (e.g., doped silicon), metallic materials (e.g., tungsten, titanium, and/or tantalum), metal-semiconductor compounds (e.g., metal silicide), and/or conductive metal nitride materials (e.g., titanium nitride, tantalum nitride, and/or tungsten nitride).

Data storage structures DS may be disposed on the second lower interlayer insulating layer 110. The data storage structures DS may be two-dimensionally arranged in the first and second directions D1 and D2, when viewed in a plan view. The data storage structures DS may be connected to second lower contact plugs 120, respectively. Each of the data storage structures DS may include a bottom electrode BE, a magnetic tunnel junction pattern MTJ, and a top electrode TE. The bottom electrode BE may be in contact with each of the second lower contact plugs 120. In an embodiment, the bottom electrode BE may be formed of or include one or more conductive metal nitride materials (e.g., TiN or TaN). The magnetic tunnel junction pattern MTJ may be provided between the bottom electrode BE and the top electrode TE. The top electrode TE may be formed of or include metallic materials (e.g., Ta, W, Ru, and Ir) and/or conductive metal nitride materials (e.g., TiN and TaN). The magnetic tunnel junction pattern MTJ may include the first magnetic pattern MP1, the second magnetic pattern MP2, and the tunnel barrier pattern TBP therebetween. The first magnetic pattern MP1 may be provided between the bottom electrode BE and the tunnel barrier pattern TBP, and the second magnetic pattern MP2 may be provided between the top electrode TE and the tunnel barrier pattern TBP. In an embodiment, the tunnel barrier pattern TBP may include a magnesium oxide layer, a titanium oxide layer, an aluminum oxide layer, a magnesium-zinc oxide layer, and/or a magnesium-boron oxide layer.

An upper insulating layer may be provided on and may at least partially cover the data storage structures DS. The upper insulating layer may include a protection insulating layer 170 and an upper interlayer insulating layer 180.

The upper interlayer insulating layer 180 may be provided on the second lower interlayer insulating layer 110. The upper interlayer insulating layer 180 may at least partially fill a space between the data storage structures DS. The upper interlayer insulating layer 180 may be formed of or include oxide, nitride, and/or oxynitride materials.

The protection insulating layer 170 may be interposed between a side surface of each of the data storage structures DS and the upper interlayer insulating layer 180 and may extend into a space between the recessed top surface 110U of the second lower interlayer insulating layer 110 and the upper interlayer insulating layer 180. The protection insulating layer 170 may include a material having an etch selectivity with respect to the upper interlayer insulating layer 180 and the second lower interlayer insulating layers 110. For example, the upper interlayer insulating layer 180 and the second lower interlayer insulating layers 110 may be formed of or include silicon oxide, and the protection insulating layer 170 may be formed of or include silicon nitride.

An upper interconnection line 200 may be disposed on the upper interlayer insulating layer 180 and may be connected to the top electrode TE. The upper interconnection line 200 may extend in the second direction D2. The upper interconnection line 200 may be connected to the magnetic tunnel junction pattern MTJ through the top electrode TE and may be used as the bit line BL of FIG. 1. The upper interconnection line 200 may be formed of or include metallic materials (e.g., copper) and/or conductive metal nitride materials.

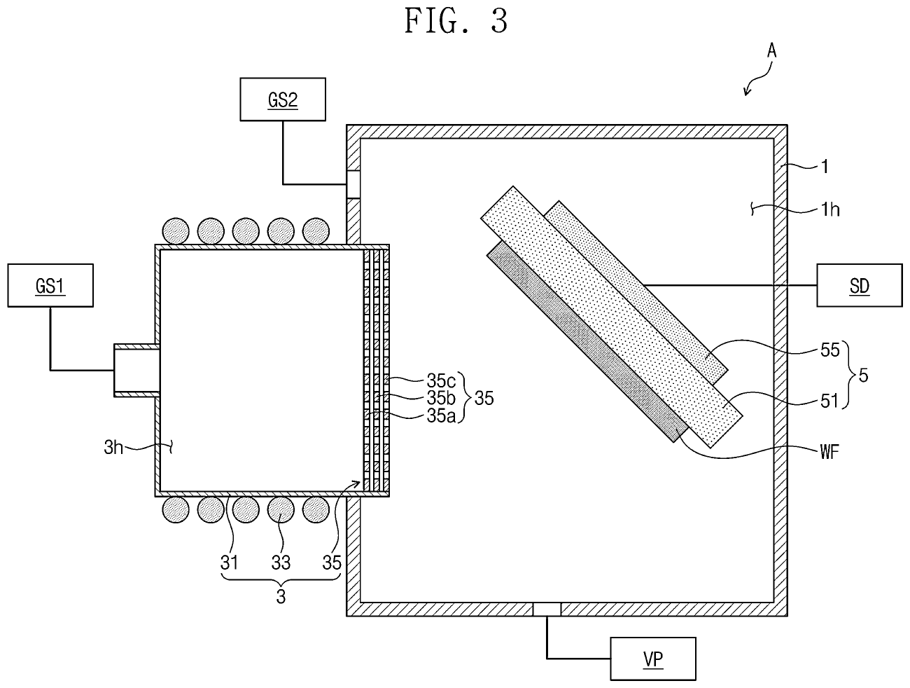

FIG. 3 is a schematic diagram illustrating a substrate processing apparatus, which is operated using an ion beam and is used for a process of fabricating a magnetic memory device, according to an embodiment of the inventive concept.

Referring to FIG. 3, a substrate processing apparatus A may be provided. The substrate process apparatus A may be an apparatus that is configured to process a substrate using an ion beam. For example, the substrate process apparatus A may be configured to perform an etching process on a substrate using an ion beam. In the present specification, the term ‘substrate’ may mean a silicon wafer, but embodiments of the inventive concept are not limited thereto. The substrate processing apparatus A may include an ion beam source chamber 3, a process chamber 7, a substrate holder 9, a first gas supplying part GS1, a second gas supplying part GS2, and a vacuum pump VP.

The ion beam source chamber 3 may be configured to produce an ion beam. More specifically, the ion beam may be composed of ions, which are extracted from plasma by the ion beam source chamber 3. The ion beam, which is emitted from the ion beam source chamber 3, may be incident into a process chamber 1. The ion beam may be used to process the substrate. For this, the ion beam source chamber 3 may include a plasma chamber 31, a plasma generator 33, a grid 35, and a grid driving device.

The plasma chamber 31 may be configured to provide a plasma generating space 3h. The plasma generating space 3h may be connected to the first gas supplying part GS1. In the plasma generating space 3h, the plasma may be generated from a portion of the gas, which is supplied from the first gas supplying part GS1.

The plasma generator 33 may be coupled to the plasma chamber 31. The plasma generator 33 may be configured to generate the plasma in the plasma generating space 3h. For this, the plasma generator 33 may include an RF coil. The RF coil may be provided to enclose the plasma chamber 31. The RF coil may be used to generate an electric field and/or a magnetic field in the plasma generating space 3h. In this case, plasma may be generated from a portion of the gas, which is supplied into the plasma generating space 3h. In other words, the plasma may be generated in the plasma generating space 3h in an inductively-coupled plasma (ICP) manner. However, embodiments of the inventive concept are not limited to this example, and in an embodiment, the plasma generator 33 may be configured to include a device that is different from the RF coil.

The grid 35 may be connected to the plasma chamber 31. The grid 35 may be configured to extract ions from the plasma in the plasma generating space 3h. In an embodiment, a plurality of grids 35 may be provided. For example, a first grid 35a, a second grid 35b, and a third grid 35c may be provided, as shown in FIG. 3. Each of the first, second, and third grids 35a, 35b, and 35c may have a plate-shaped structure. For example, each of the first, second, and third grids 35a, 35b, and 35c may be shaped like a circular plate. The ions, which are extracted from the plasma in the plasma generating space 3h, may sequentially pass through the first, second, and third grids 35a, 35b, and 35c and may be moved into the process chamber 1. The third grid 35c may be grounded. For example, the third grid 35c may be a ground grid. The second grid 35b may be a screen grid. In an embodiment, the second grid 35b may be used to adjust an amount of ions passing through the same. The first grid 35a may be an accelerating grid. The ion beam may be accelerated by a potential difference between the third grid 35c and the first grid 35a and may be incident into a process target substrate WF.

The first gas supplying part GS1 may be connected to the plasma generating space 3h. The first gas supplying part GS1 may be configured to supply a plasma generating gas into the plasma chamber 31. In an embodiment, the plasma generating gas may contain an inert gas (e.g., an argon (Ar) gas). For this, the first gas supplying part GS1 may include a gas tank, a compressor, and a valve.

The process chamber 1 may be configured to provide a process space 1h. A process on the process target substrate WF may be performed in the process space 1h. The process chamber 1 may be connected to the ion beam source chamber 3. For example, the ion beam source chamber 3 may be coupled to a side portion of the process chamber 1. The plasma generating space 3h and the process space 1h may be connected to each other through the grid 35. However, embodiments of the inventive concept are not limited to this example, and in an embodiment, the process chamber 1 may be provided to enclose the ion beam source chamber 3. In other embodiments, the process chamber 1 and the ion beam source chamber 3 may be disposed to be spaced apart from each other.

A substrate supporting portion 5 may include a substrate holder 51 and a substrate holder adjusting device 55.

The substrate holder 51 may be placed in the process chamber 1. The substrate holder 51 may be spaced apart from the ion beam source chamber 3. For example, the substrate holder 51 may be spaced apart from the ion beam source chamber 3 in a downward direction, as shown in FIG. 3. The substrate holder 51 may fasten the substrate to a specific position in the process space 1h. For this, the substrate holder 51 may include an electrostatic chuck (ESC) and/or a vacuum chuck. However, embodiments of the inventive concept are not limited to this example, and the process target substrate WF may be disposed on the substrate holder 51 without an additional fastening force.

The substrate holder adjusting device 55 may be configured to change an inclination angle of the substrate holder 51 and/or to rotate the substrate holder 51. For this, the substrate holder adjusting device 55 may include an actuator (e.g., a motor). A substrate driving device SD may be configured to change an inclination angle of the substrate supporting portion 5 or to rotate the substrate supporting portion 5. More specifically, the substrate driving device SD may be configured to adjust an inclination angle of the substrate holder adjusting device 55 and apply a rotating power to the substrate holder adjusting device 55, and in this case, the substrate holder adjusting device 55 may be used to change the inclination angle of the substrate holder 51 or to rotate the substrate holder 51.

The second gas supplying part GS2 may be connected to the process space 1h. The second gas supplying part GS2 may be configured to supply a process gas into the process chamber 1. In an embodiment, the process gas may be a neutral gas that is electrically neutral. For example, the neutral gas may include alcohol (e.g., CH₃OH). For this, the second gas supplying part GS2 may include a gas tank, a compressor, and a valve.

The vacuum pump VP may be connected to the process space 1h. During the process, the process space 1h may be maintained in a substantially vacuum state by the vacuum pump VP. The vacuum pump VP may be operated during the supplying of the plasma generating gas and the process gas.

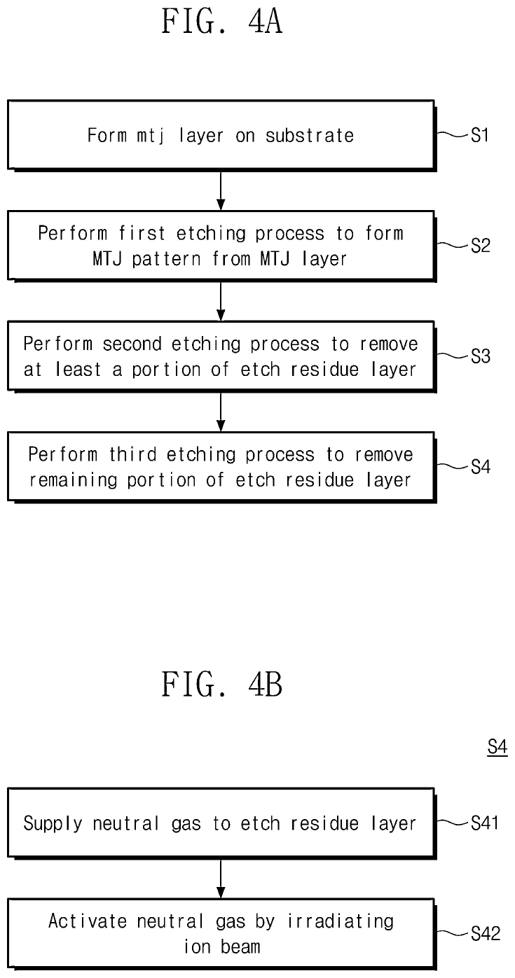

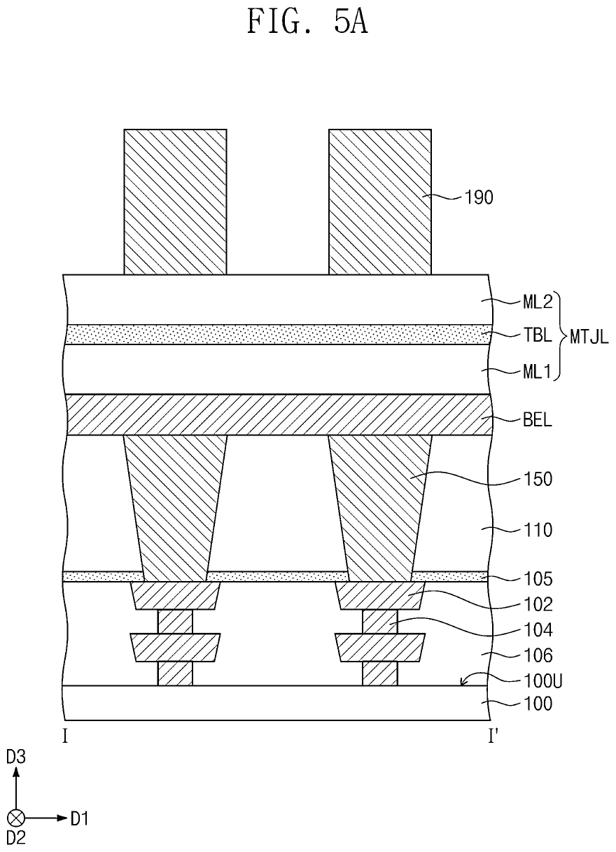

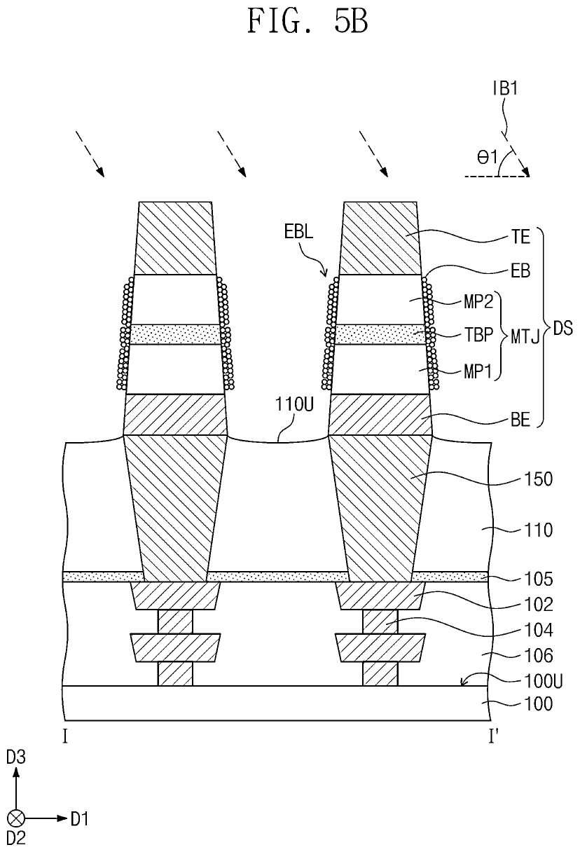

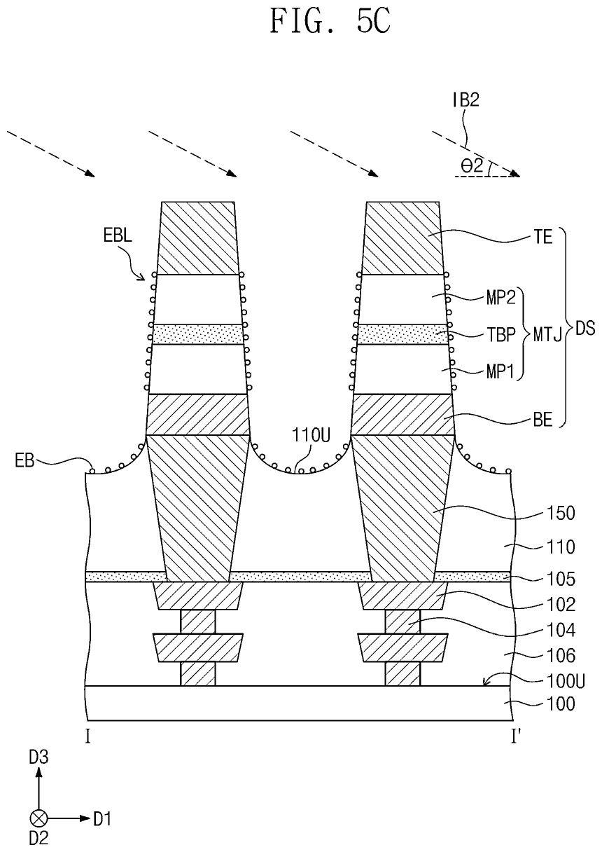

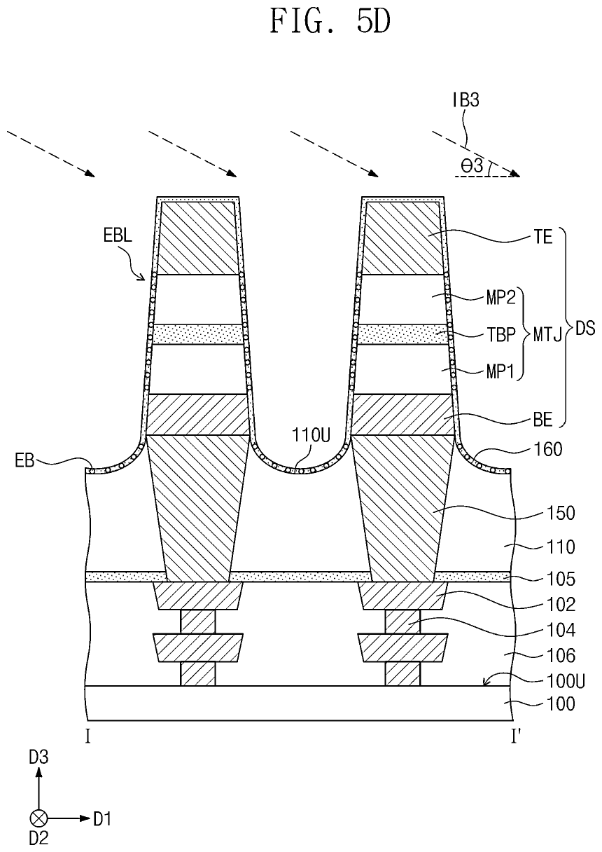

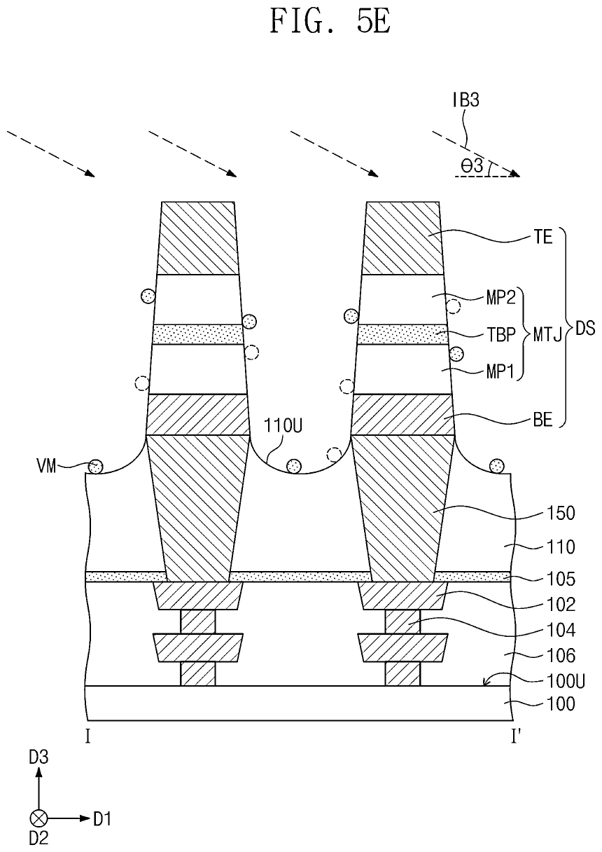

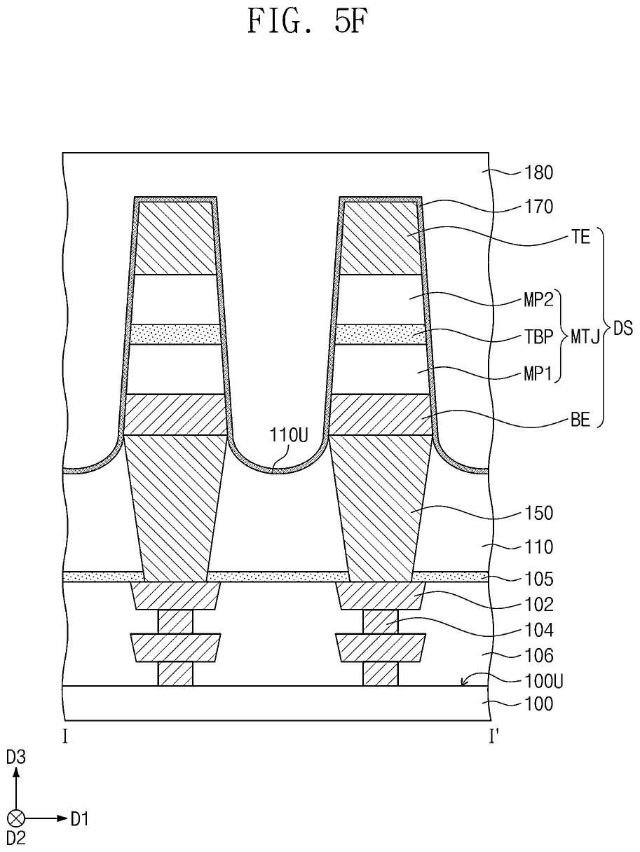

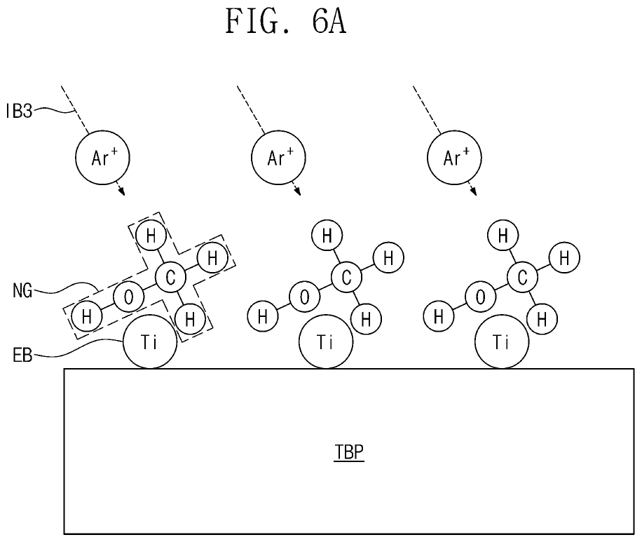

FIG. 4A is a flow chart illustrating a method of fabricating a magnetic memory device, according to an embodiment of the inventive concept. FIG. 4B is a flow chart illustrating the operation S4 of FIG. 4A. FIGS. 5A to 5F are sectional views, which are taken along the line I-I′ of FIG. 2 to illustrate a method of fabricating a magnetic memory device according to an embodiment of the inventive concept.

Referring to FIGS. 4A and 5A, a magnetic tunnel junction (MTJ) layer (MTJL) may be formed on the substrate 100 (in S1). First, the substrate 100 may be prepared. The selection elements SE of FIG. 3 may be formed on the substrate 100, and an interconnection structure 102/104 may be formed on the selection elements SE. The interconnection structure 102/104 may include the lower interconnection lines 102 and the lower contacts 104 connected to the lower interconnection lines 102. The first lower interlayer insulating layer 106 on and at least partially covering the lower interconnection lines 102 may be formed on the substrate 100. The first lower interlayer insulating layer 106 may be formed to expose at least a portion of top surfaces of the uppermost ones of the lower interconnection lines 102. The etch stop layer 105 and the second lower interlayer insulating layer 110 may be formed on the first lower interlayer insulating layer 106. The lower contact plugs 150 may be formed to extend through or penetrate the second lower interlayer insulating layer 110 and the etch stop layer 105. The lower contact plugs 150 may be connected to the lower interconnection lines 102, respectively. A bottom electrode layer BEL and the magnetic tunnel junction layer MTJL may be sequentially formed on the second lower interlayer insulating layer 110. In an embodiment, the magnetic tunnel junction layer MTJL may include a first magnetic layer ML1, a tunnel barrier layer TBL, and a second magnetic layer ML2, which are sequentially stacked on the bottom electrode layer BEL. The first and second magnetic layers ML1 and ML2 may correspond to a reference layer and a free layer, respectively. In an embodiment, the bottom electrode layer BEL and the magnetic tunnel junction layer MTJL may be formed using a sputtering deposition process. A conductive mask pattern 190 may be formed on the magnetic tunnel junction layer MTJL. The conductive mask pattern 190 may define regions, in which the magnetic tunnel junction patterns MTJ to be described below will be formed, and may be used as the top electrode TE of the data storage structure DS. The conductive mask pattern 190 may be formed of or include metallic materials (e.g., Ta, W, Ru, Ir, and Ti) and/or conductive metal nitride materials (e.g., TiN and TaN).

Referring to FIGS. 3, 4A, and 5B, the substrate 100 with the magnetic tunnel junction layer MTJL may be disposed on the substrate holder 51 of FIG. 3. Hereinafter, the substrate 100, on which the magnetic tunnel junction layer MTJL or the magnetic tunnel junction pattern MTJ is formed, will be referred to as the process target substrate WF. In an embodiment, the placing of the process target substrate WF in the substrate processing apparatus may be performed before the formation of the conductive mask pattern 190. The magnetic tunnel junction layer MTJL and the conductive mask pattern 190 may face the ion beam source chamber 3 and may be spaced apart from the ion beam source chamber 3 in an inclined shape. The substrate holder 51 may be configured to fasten the process target substrate WF to a specific position. For example, the substrate holder 51 may be configured to fasten the process target substrate WF to a specific position in the process space 1h using an electrostatic force and/or a vacuum pressure. The process target substrate WF, which is disposed on the substrate holder 51, may be spaced apart from the ion beam source chamber 3.

A first etching process may be performed to form the magnetic tunnel junction pattern MTJ from the magnetic tunnel junction layer MTJL (in S2 of FIG. 4A). The first etching process may be performed to form the bottom electrode BE from the bottom electrode layer BEL. In detail, a plasma generating gas may be supplied from the first gas supplying part GS1 of FIG. 3 into the plasma chamber 31. The plasma generating gas may include one of argon (Ar), neon (Ne), xenon (Xe), krypton (Kr), helium (He), oxygen (O₂), hydrogen (H₂), and ammonia (NH₃). In an embodiment, the plasma generating gas may be argon (Ar). Plasma may be generated from a portion of the plasma generating gas in the plasma generating space 3h by the plasma generator 33. The emission of the ion beam from the ion beam source chamber 3 may include extracting ions from the plasma using the grid 35. The ions may be supplied into the process space 1h through the grid 35. The ion beam may be incident into the process target substrate WF, and in this case, the magnetic tunnel junction pattern MTJ and the bottom electrode BE may be formed by sequentially etching the magnetic tunnel junction layer MTJL and the bottom electrode layer BEL using the conductive mask pattern 190 as an etch mask.

During the first etching process, a first ion beam IB1 may be incident into the process target substrate WF or the substrate 100 at a first inclination angle Θ1. The first inclination angle Θ1 may range from 60° to 70°. In the present specification, the inclination angle may be an angle between the top surface 100U of the substrate 100 and the ion beam or between a horizontal surface (i.e., a surface in a plane defined by the D1 and D2 directions) and the ion beam. The first ion beam IB1 may be accelerated by a first potential difference. The first potential difference may be greater than or equal to 1000 V. In the present specification, the potential difference may mean a potential difference between the third grid 35c and the first grid 35a. The second magnetic layer ML2, the tunnel barrier layer TBL, the first magnetic layer ML1, and the bottom electrode layer BEL may be sequentially etched to form the second magnetic pattern MP2, the tunnel barrier pattern TBP, the first magnetic pattern MP1, and the bottom electrode BE, respectively. A remaining portion of the conductive mask pattern 190, which is left on the magnetic tunnel junction pattern MTJ after the etching of the magnetic tunnel junction layer MTJL and the bottom electrode layer BEL, may be referred to as the top electrode TE. The top electrode TE, the second magnetic pattern MP2, the tunnel barrier pattern TBP, the first magnetic pattern MP1, and the bottom electrode BE may be referred to as the data storage structure DS. The top surface 110U of the second lower interlayer insulating layer 110 between the data storage structures DS may be recessed by the first etching process.

An etch residue EB may be produced in the first etching process. The magnetic tunnel junction pattern MTJ, the bottom electrode BE, and the top electrode TE may contain a large amount of metallic materials. As a result, an etching process for forming the data storage structure DS may have a low etch rate and a risk generating a lot of etch residues EB, compared with an etching process on a silicon layer or an insulating layer. The etch residues EB may be left on a side surface of the magnetic tunnel junction pattern MTJ to form an etch residue layer EBL. Since the etch residue layer EBL is re-deposited, it may also be referred to as a redeposition layer. For example, the etch residues EB may be formed of or include a metallic material. In the case where the etch residue layer EBL is attached to a side surface of the tunnel barrier pattern TBP, a short circuit issue may occur between the first magnetic pattern MP1 and the second magnetic pattern MP2, during the operation of the magnetic memory device. During the first etching process, the vacuum pump VP of FIG. 3 may be constantly operated to exhaust the removed etch residues EB to the outside of the chamber.

Referring to FIGS. 3, 4A, and 5C, a second etching process may be performed on the etch residue layer EBL (in S2). At least a portion of the etch residue layer EBL may be removed by the second etching process. The second etching process may be referred to as a trimming process. The plasma generating gas may be supplied from the first gas supplying part GS1 of FIG. 3 into the plasma chamber 31, and the plasma generating gas may be the same gas as that in the first etching process. For example, the plasma generating gas may contain argon (Ar). The second etching process may be performed in the same process chamber (i.e., the process chamber 1) as that for the first etching process. During the second etching process, a second ion beam IB2 may be incident into the process target substrate WF or the substrate 100 at a second inclination angle Θ2. The second inclination angle Θ2 of the second ion beam IB2 may be smaller than the first inclination angle Θ1 of the first ion beam IB1. For example, the second inclination angle Θ2 may range from 30° to 50°. An ion beam IB may be accelerated by a second potential difference. The second potential difference may be less than the first potential difference. The second potential difference may be less than or equal to 300 V. As an example, the second potential difference may range from 20 V to 300 V. As another example, the second potential difference may range from 200 V to 300 V. A recess depth of the top surface 110U of the second lower interlayer insulating layer 110 between the data storage structures DS may be increased by the second etching process. In the first etching process, the etch residues EB may be attached to the top surface 110U of the second lower interlayer insulating layer 110 between the data storage structures DS. Alternatively, in the second etching process, a portion of the etch residue layer EBL may be detached from the side surfaces of the data storage structures DS and may be again attached to the top surface 110U of the second lower interlayer insulating layer 110 between the data storage structures DS. In the case where the etch residue layer EBL is left between adjacent ones of the data storage structures DS, the adjacent ones of the data storage structures DS may be unintentionally connected to each other. During the second etching process, the etch residue layer EBL may be partially removed from the side surfaces of the data storage structures DS and from the top surface 110U of the second lower interlayer insulating layer 110 between adjacent ones of the data storage structures DS. However, since a pitch between adjacent ones of the data storage structures DS is small (e.g., less than 100 nm), the etch residue layer EBL may not be sufficiently removed. During the second etching process, the vacuum pump VP of FIG. 3 may be constantly operated to exhaust the removed etch residues EB to the outside of the chamber.

Referring to FIGS. 3, 4A, 4B, 5C, and 5D, a third etching process may be performed to remove the etch residue layer. The third etching process may include supplying a neutral gas to the etch residue layer (in S41) and irradiating an ion beam to activate the neutral gas (in S42). The activation of the neutral gas may mean formation of a new compound, which is caused by the reaction between the neutral gas and the etch residue.

The neutral gas may be supplied from the second gas supplying part GS2 of FIG. 3 to the process chamber 1. In an embodiment, the neutral gas may be a non-charged gas, in which positive or negative charges are absent. The neutral gas may include an organic compound containing the hydroxyl group (—OH). The neutral gas may include methanol (CH₃OH), ethanol (C₂H₅OH), acetic acid (CH₃COOH), 1-propanol (CH₃CH₂CH₂OH), 2-propanol (CH₃CHOHCH₃), butyl alcohol (C₄H₉OH), aminomethanol (NH₂CH₂OH), glycerol (C₃H₈O₃), and/or ethylene glycol (C₂H₆O₂). As shown in FIG. 5C, the neutral gas may be adsorbed on and diffused into the top and side surfaces of the data storage structures DS and the top surface 110U of the second lower interlayer insulating layer 110 between adjacent ones of the data storage structures DS to form an adsorption layer 160. The adsorption layer 160 may be on and at least partially cover a remaining portion of the etch residue layer EBL.

While the gas is supplied from the second gas supplying part GS2, a third ion beam IB3 may be incident into the process target substrate WF or the substrate 100 from the ion beam source chamber 3. The plasma generating gas may be supplied from the first gas supplying part GS1 of FIG. 3 into the plasma chamber 31, and the plasma generating gas may be the same gas as that in the first etching process. For example, the plasma generating gas may contain argon. The third etching process may be performed in the same process chamber (i.e., the process chamber 1) as that for the first etching process. The third ion beam IB3 may be incident at a third inclination angle Θ3. The third inclination angle Θ3 may be smaller than the first inclination angle Θ1. For example, the third inclination angle Θ3 may range from 30° to 50°. The ion beam IB may be accelerated by a third potential difference. The third potential difference may be less than the first potential difference. The third potential difference may be less than or equal to 300 V. As an example, the third potential difference may range from 100 V to 300 V. As another example, the third potential difference may range from 200 V to 300 V. The third potential difference and the third inclination angle Θ3, which are related to the third ion beam IB in the third etching process, may be the same as or similar to the second potential difference and the second inclination angle Θ2, respectively, which are related to the second ion beam IB2 in the second etching process. In an embodiment, the third etching process may be performed when the process space 1h of the process chamber 1 has an internal pressure ranging from 0.2 mT to 0.5 mT.

The adsorption layer 160 and the etch residue layer EBL may be further removed by the third etching process. In some embodiments, the adsorption layer 160 and the etch residue layer EBL may be completely removed. In other embodiments, some portion of the adsorption layer 160 and/or the etch residue layer EBL may remain. In detail, ions (e.g., argon ions) of the third ion beam IB3 may collide with the adsorbed gas to activate the gas. Owing to the reaction between the activated gas and the etch residue EB, the etch residue EB may be oxidized and may be replaced with a volatile material VM.

During the supplying of the neutral gas and the irradiation of the third ion beam 1B3, the vacuum pump VP of FIG. 3 may be constantly operated to exhaust the neutral gas and the volatile material VM, which are not adsorbed and are left, to the outside of the chamber.

According to an embodiment of the inventive concept, the irradiation of the third ion beam IB3 may be performed after the supplying of the neutral gas.

Referring to FIG. 5F, the protection insulating layer 170 may be formed on the second lower interlayer insulating layer 110. The protection insulating layer 170 may be provided to conformally be on and at least partially cover the top and side surfaces of each of the data storage structures DS and may be extended along the recessed top surface 110U of the second lower interlayer insulating layer 110. Next, the upper interlayer insulating layer 180 may be formed to at least partially fill a space between the data storage structures DS and to cover the protection insulating layer 170 and the data storage structures DS.

Referring back to FIG. 2B, the upper interlayer insulating layer 180 and the protection insulating layer 170 may be partially removed to expose a top surface of the top electrode TE. The partial removal of the upper interlayer insulating layer 180 and the protection insulating layer 170 may include performing a planarization process to expose the top surface of the top electrode TE. In an embodiment, the planarization process may include a chemical mechanical polishing (CMP) process or an etch-back process.

The upper interconnection line 200 may be formed on the upper interlayer insulating layer 180. The upper interconnection line 200 may be on and at least partially cover the exposed top surface of the top electrode TE. Thus, the upper interconnection line 200 may be electrically connected to the top electrode TE.

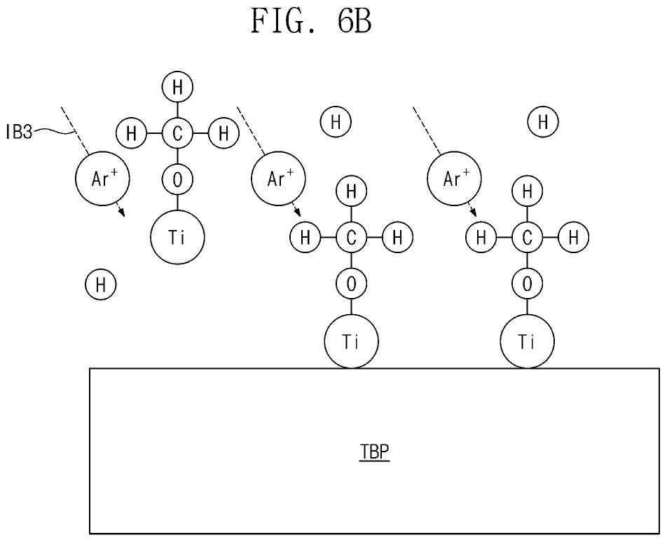

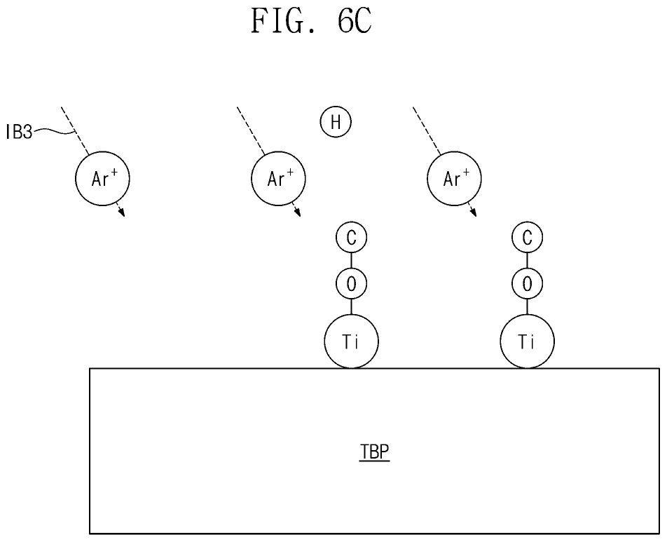

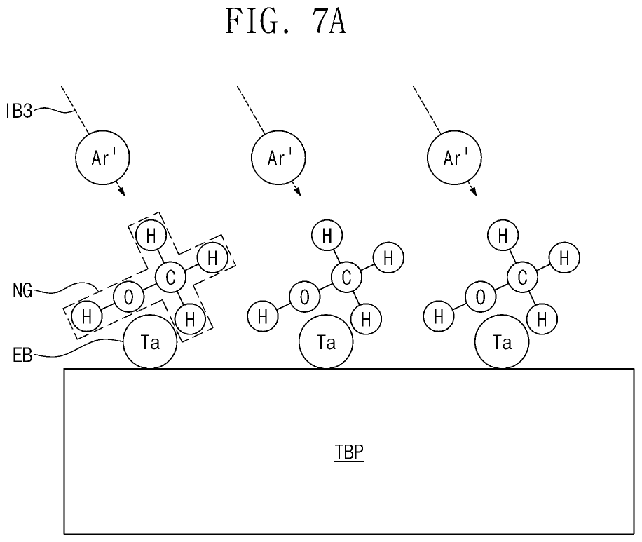

FIGS. 6A to 6C are conceptual diagrams illustrating a process of removing an etch residue, which is shown in FIGS. 5D and 5E, according to an embodiment of the inventive concept.

Referring to FIGS. 5D and 6A, a neutral gas NG may be adsorbed on the etch residue EB, which is disposed on the side surface of the tunnel barrier pattern TBP. For example, the etch residue EB may be a titanium (Ti) particle. In an embodiment, the neutral gas NG may be a gas of methanol (CH₃OH).

Referring to FIGS. 5E and 6B, the third ion beam IB3 may be irradiated to the adsorbed neutral gas, and in this case, the energy of argon ion (Ar⁺) may be supplied to the adsorbed neutral gas. During this process, O—H bonds of methanol (CH₃OH) may be broken and H may be removed to form Ti—O—CH₃ molecules. Some of the Ti—O—CH₃ molecules may be volatilized.

Referring to FIGS. 6E and 6C, the third ion beam IB3 may be constantly irradiated to supply an ion energy to the non-volatilized Ti—O—CH₃ molecules, and in this case, H may be removed to form Ti—O—C molecules. That is, the etch residue may be oxidized.

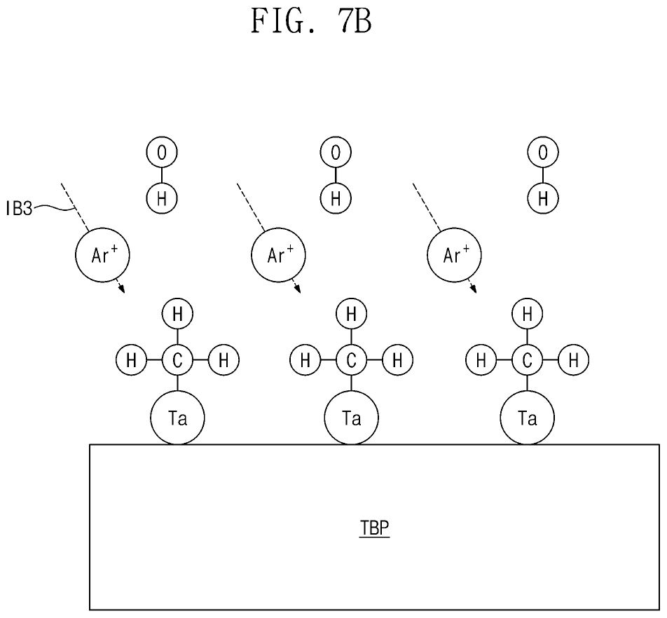

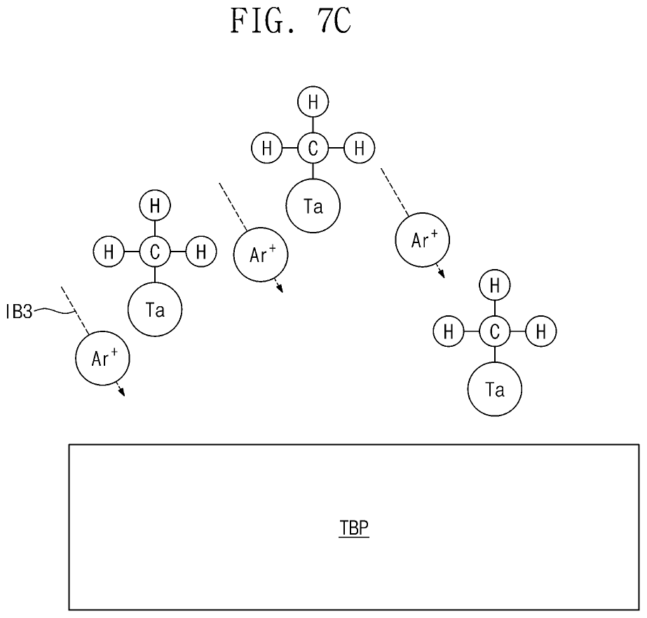

FIGS. 7A to 7C are conceptual diagrams illustrating a process of removing an etch residue, which is shown in FIGS. 5D and 5E, according to an embodiment of the inventive concept.

Referring to FIGS. 5D and 7A, the neutral gas NG may be adsorbed on the etch residue EB, which is disposed on the side surface of the tunnel barrier pattern TBP. The etch residue EB may be, for example, a tantalum (Ta) particle. The neutral gas NG may be, for example, a methanol (CH₃OH) gas.

Referring to FIGS. 5D and 7B, the third ion beam IB3 may be irradiated to the adsorbed neutral gas, and in this case, the energy of argon ion (Ar⁺) may be supplied to the adsorbed neutral gas. During this process, CH₃—OH bonds of methanol (CH₃OH) may be broken and —OH may be removed to form Ta—CH₃ molecules.

Referring to FIGS. 6E and 6C, the third ion beam IB3 may be constantly irradiated, and in this case, the highly volatile Ta—CH₃ molecules may be exposed to the energy of the ions and may be volatilized.

According to an embodiment of the inventive concept, the etch residue may be efficiently removed in its entirety or in part by adsorbing the neutral gas on the etch residue layer and activating the neutral gas using the ion beam.

According to an embodiment of the inventive concept, the third etching process may be performed in the same process chamber as that for the first and second etching processes. In addition, the third etching process may be performed under the same or similar condition as that for the second etching process, except for the supplying of the neutral gas. Each of the first to third etching processes may be an ion beam etching process. Thus, the overall etching process may be performed efficiently.

According to an embodiment of the inventive concept, in the third etching process, the supplying of the neutral gas and the incidence of the third ion beam may be performed at the same time. As a result, the etching process may be efficiently performed, compared to when these operations are separately performed. In addition, because a vacuum pump is also operated at the same time, the etching process may be performed efficiently.

According to an embodiment of the inventive concept, in the third etching process, a gas containing an organic compound with the hydroxyl group may be supplied in a neutral state, not in the form of radicals or ions, to perform an ion beam etching process. Thus, it may be possible to prevent the magnetic tunnel junction pattern from being damaged and to prevent an undesired by-product from being produced through reaction with the magnetic tunnel junction pattern, compared with a reactive ion etching (RIE) process, in which a gas containing the organic compound with the hydroxyl group is supplied in the form of radicals or ions.

According to an embodiment of the inventive concept, because the second etching process is performed between the first etching process and the third etching process, it may be possible to more effectively remove the etch residue in the third etching process.

According to an embodiment of the inventive concept, in the third etching process, the ion beam may be irradiated at the third inclination angle smaller than the first inclination angle, and in this case, the etch residue may be effectively removed.

In a method of fabricating a magnetic memory device according to an embodiment of the inventive concept, it may be possible to effectively remove a conductive etch residue, which is produced during a process of forming a magnetic tunnel junction pattern. Accordingly, it may be possible to improve the reliability of the magnetic memory device.

While example embodiments of the inventive concept have been particularly shown and described, it will be understood by one of ordinary skill in the art that variations in form and detail may be made therein without departing from the spirit and scope of the attached claims.

What is claimed is:

1. A method of fabricating a magnetic memory device, comprising:
sequentially forming a first magnetic layer, a tunnel barrier, and a second magnetic layer on a substrate;
performing a first etching process of sequentially etching the second magnetic layer, the tunnel barrier, and the first magnetic layer to form a magnetic tunnel junction pattern and an etch residue layer on a side surface of the magnetic tunnel junction pattern;
performing a second etching process to remove at least a portion of the etch residue layer; and
performing a third etching process to remove an additional portion of the etch residue layer, after the second etching process,
wherein the third etching process comprises:
supplying a neutral gas onto the etch residue layer; and
irradiating a first ion beam at a first inclination angle relative to a top surface of the substrate.

2. The method of claim 1, wherein the neutral gas comprises methanol (CH₃OH), ethanol (C₂H₅OH), acetic acid (CH₃COOH), 1-propanol (CH₃CH₂CH₂OH), 2-propanol (CH₃CHOHCH₃), butyl alcohol (C₄H₉OH), aminomethanol (NH₂CH₂OH), glycerol (C₃H₈O₃), or ethylene glycol (C₂H₆O₂) or a combination thereof.

3. The method of claim 1, wherein the first etching process, the second etching process, and the third etching process are performed in a same process chamber.

4. The method of claim 3, wherein the supplying of the neutral gas further comprises adsorbing the neutral gas on the etch residue layer.

5. The method of claim 1, wherein the first inclination angle ranges from 30° to 50°.

6. The method of claim 1, wherein the first ion beam is accelerated by a first potential difference, and
wherein the first potential difference is less than or equal to 300 V.

7. The method of claim 1, wherein the first etching process comprises irradiating a second ion beam at a second inclination angle relative to the top surface of the substrate, and
wherein the second inclination angle is greater than the first inclination angle.

8. The method of claim 7, wherein the second inclination angle ranges from 60° to 70°.

9. The method of claim 7, wherein the second ion beam is accelerated by a second potential difference, and
wherein the second potential difference is greater than or equal to 1000 V.

10. The method of claim 1, wherein the supplying of the neutral gas and the irradiating of the first ion beam are performed simultaneously.

11. The method of claim 1, wherein the irradiating of the first ion beam is performed after the supplying of the neutral gas.

12. A method of fabricating a magnetic memory device, comprising:
sequentially forming a first magnetic layer, a tunnel barrier, and a second magnetic layer on a substrate;
performing a first etching process of sequentially etching the second magnetic layer, the tunnel barrier, and the first magnetic layer to form a magnetic tunnel junction pattern and an etch residue layer on a side surface of the magnetic tunnel junction pattern;
performing a second etching process to remove at least a portion of the etch residue layer; and
performing a third etching process to remove an additional portion of the etch residue layer, after the second etching process,
wherein the first etching process, the second etching process, and the third etching process comprise a first ion beam etching process, a second ion beam etching process, and a third ion beam etching process, respectively,
wherein the third etching process further comprises supplying a neutral gas onto the etch residue layer, and
wherein the supplying of the neutral gas and the third ion beam etching process are performed simultaneously.

13. The method of claim 12, wherein the neutral gas comprises methanol (CH₃OH), ethanol (C₂H₅OH), acetic acid (CH₃COOH), 1-propanol (CH₃CH₂CH₂OH), 2-propanol (CH₃CHOHCH₃), butyl alcohol (C₄H₉OH), aminomethanol (NH₂CH₂OH), glycerol (C₃H₈O₃), or ethylene glycol (C₂H₆O₂) or a combination thereof.

14. The method of claim 12, wherein the first ion beam etching process comprises irradiating a first ion beam onto the substrate at a first inclination angle relative to a top surface of the substrate,
wherein the second ion beam etching process comprises irradiating a second ion beam onto the substrate at a second inclination angle relative to the top surface of the substrate,
wherein the third ion beam etching process comprises irradiating a third ion beam onto the substrate at a third inclination angle relative to the top surface of the substrate, and
wherein the second and third inclination angles are smaller than the first inclination angle.

15. The method of claim 14, wherein the first inclination angle ranges from 60° to 70°, and
wherein the second and third inclination angles range from 30° to 50°.

16. The method of claim 14, wherein the first ion beam is accelerated by a first potential difference,
wherein the second ion beam is accelerated by a second potential difference,
wherein the third ion beam is accelerated by a third potential difference, and
wherein the second and third potential differences are less than the first potential difference.

17. The method of claim 16, wherein the first potential difference is greater than or equal to 1000 V, and
wherein the second potential difference and the third potential difference is less than or equal to 300 V.

18. A method of fabricating a magnetic memory device, comprising:
sequentially forming a first magnetic layer, a tunnel barrier, and a second magnetic layer on a substrate;
performing a first etching process of sequentially etching the second magnetic layer, the tunnel barrier, and the first magnetic layer to form a magnetic tunnel junction pattern and an etch residue layer on a side surface of the magnetic tunnel junction pattern;
performing a second etching process to remove at least a portion of the etch residue layer; and
performing a third etching process to remove an additional portion of the etch residue layer, after the second etching process,
wherein the first etching process, the second etching process, and the third etching process comprise a first ion beam etching process, a second ion beam etching process, and a third ion beam etching process, respectively,
wherein the third etching process further comprises supplying a neutral gas onto the etch residue layer,
wherein the first, second, and third etching processes are performed in a same process chamber, and
wherein a vacuum pump connected to the process chamber is operated during the supplying of the neutral gas and the third ion beam etching process.

19. The method of claim 18, wherein the neutral gas comprises methanol (CH₃OH), ethanol (C₂H₅OH), acetic acid (CH₃COOH), 1-propanol (CH₃CH₂CH₂OH), 2-propanol (CH₃CHOHCH₃), butyl alcohol (C₄H₉OH), aminomethanol (NH₂CH₂OH), glycerol (C₃H₈O₃), or ethylene glycol (C₂H₆O₂) or a combination thereof.

20. The method of claim 18, wherein the supplied neutral gas is in an ion-free or radical-free state.
